(19) United States
(12) Patent Application Publication
(10) Pub. No.: US 2002/0117672 A1
(43) Pub. Date: Aug. 29, 2002

(54) High-brightness blue-light emitting crystalline structure

(76) Inventors: Ming-Sung Chu, Taichung (TW); Shi-Kun Chen, Taichung (TW); Chun-Yung Sung, Taichung (TW); Liang-Tung Chang, Taichung (TW)

Correspondence Address: Supreme Patent Services, Post Office Box 3318, Saratoga, CA, 95070, US

(21) Appl. No.: 09/792,446

(22) Filed: Feb. 23, 2001

(51) Int. Cl. H01L 27/15; H01L 31/12; H01L 33/00

(52) U.S. Cl. 257/79

(57) ABSTRACT

A high-brightness blue-light emitting crystalline structure is provided for enhancing illuminating intensity of a blue-light emitting diode by taking advantage of a sapphire substrate, which is provided with a multi-layer distributed Bragg reflector (DBR) or a plated mirror layer on its surface for reflecting a part of the light created from a P-GaN surface so as to supplement the other part of light, which penetrates a transparent conductive layer directly. And, indium tin oxide is adopted for serving as a transparent conductive layer of blue-light emitting diode, or an extraordinarily thin nickel/aurum layer is plated on the P-GaN surface precedently before forming the ITO conductive layer to thereby care both the light-permeability and the ohmic contact resistance. A plurality of anti-reflection coatings (ARC) is formed on the ITO conductive layer for the enhancement of blue-light emissivity.

### FIELD OF THE INVENTION

This invention relates generally to the structure of ohmic electrode and transparent conductive layer (TCL) of a high-brightness series of gallium nitride (GaN) blue-light emitting diode (LED), particularly to an LED structure provided with a plated mirror layer and a multi-layer distributed Bragg reflector (DBR) for enhancement of the LED's illuminating intensity.

### BACKGROUND OF THE INVENTION

In a known GaN series blue-light emitting diode, blue light is emitted by a P-N junction via a P-GaN semiconductor layer and a transparent conductive layer (TCL), and the technology and architecture concerned to the GaN series semiconductor elements made of group III-V compounds are to be described below.

As illustrated in a cutaway sectional view of a GaN series blue-light emitting diode shown in FIG. 1A, a GaN series LED made of group III-V compounds having a P-electrode 105 and an N-electrode 104 comprises:

a substrate 101 with a first and a second surface 101a, 101b;

a semiconductor stack architecture aligned on the first surface 101a of the substrate 101 further comprising a semiconductor layer 102 of group III-V compounds in N-GaN series and a semiconductor layer 103 made of group III-V compounds in P-GaN series;

the N-electrode 104 being a first electrode in connection with the N-GaN semiconductor layer 102; and

the P-electrode 105 being a light-permeable second electrode in connection with the P-GaN semiconductor layer 103, and further comprising a soldering pad 106 sitting thereon.

A created and quenched metallic layer, a Ni/Au layer for example, is provided to the second electrode 105 (a P-type contact electrode) to have the same connected to the P-GaN semiconductor layer 103. In the GaN series semiconductor elements of group III-V compounds, the first electrode 104 may be made of titanium (Ti), aluminum (Al), or aurum (Au), while the second electrode 105 may be made from any of aurum, nickel, platinum, aluminum, tin, indium, chrome, or titanium, or an alloy thereof, wherein the Ni-Au alloy is more preferable. The above said conventional LED can emit blue light from a surface of P-GaN series semiconductor layer 103 of group III-V compounds via the second electrode 105.

A Flip-Chip technology developed by Toyota Gosei Co. and Matsushita Co. Japan for making LED as shown in FIG. 1B has adopted a metallic bump 112, 113 to joint with a P-electrode 110 and an N-electrode 111 respectively instead of using wire-bonding method with a golden or aluminum wire in the conventional connection technology, wherein both the P-electrode and the N-electrode face downwardly so that the blue light created is projected out by taking advantage of a transparent sapphire base 107.

When the Flip-Chip architecture is applied in a blue-light emitting diode, the conventional transparent conductive layer (TCL) employed for emitting blue light wouldn't necessarily be transparent as long as it can disperse electric current. Hence, the LED with the Flip-Chip architecture may have the conductive layer thickened such that a reflection effect could probably be achieved in addition to the current dispersion function. However, in the Flip-Chip LED architecture, heat created by the crystalline grain is conducted to a metallic cup base of LED lamp through those two metallic bumps with poor conductivity that would degrade the quality and reliability of a packaged LED lamp.

Moreover, an oxidation measure shown in FIG. 1C is widely used for decreasing the blue-light absorptivity of a conventional P-GaN current dispersion layer, wherein a nickel layer serving as an ohmic interface is oxidized into NiO for soaring the transparency of the current dispersion layer while the conductivity of NiO oxide is fair for application. Therefore, for improvement of the blue-light LED, both the light-permeability and the ohmic contact resistor are preferably put into consideration.

### SUMMARY OF THE INVENTION

The primary object of this invention is to improve the conventional crystalline grain in order to enhance illuminating intensity of a blue-light emitting diode by taking advantage of a sapphire substrate, which is provided with a multi-layer distributed Bragg reflector (DBR) or a plated mirror layer on its surface for reflecting a part of the light created from a P-GaN surface so as to supplement the other part of light, which penetrates a transparent conductive layer directly.

Another object of this invention is to improve the heat-conductivity of a crystalline grain of Flip-Chip technology so as to prolong lifetime and upgrade reliability of a packaged LED lamp.

In order to realize above said objects, this invention has adopted indium tin oxide (ITO)—a widely used electrically conductive vitreous material in liquid crystal display (LCD) industry—to serve as a transparent conductive layer of blue-light emitting diode, or an extraordinarily thin nickel layer may be plated on the P-GaN surface precedently before forming the ITO conductive layer to thereby care concurrently the light-permeability and the ohmic contact resistance.

More particularly, this invention may further form a plurality of anti-reflection coatings (ARC) on a current dispersion layer and the transparent conductive layer for enhancement of blue-light emissivity.

For more detailed information regarding this invention together with advantages or features thereof, at least an example of preferred embodiment will be elucidated below with reference to the annexed drawings.

### BRIEF DESCRIPTION OF THE DRAWINGS

The related drawings in connection with the detailed description of this invention, which is to be made later, are described briefly as follows, in which:

FIG. 1A is a cutaway sectional view showing a conventional GaN series blue-light emitting diode;

FIG. 1B illustrates an LED made by a conventional Flip-Chip technology;

FIG. 1C is a schematic view showing an oxidation method applied for reducing blue-light absorptivity of a P-GaN current dispersion layer;

FIG. 2 illustrates a first embodiment of this invention regarding the structure of a plated mirror layer;

FIG. 3 illustrates a second embodiment of this invention regarding coarsening of the plated mirror layer,

FIG. 4 illustrates a third embodiment of this invention regarding a schematic crystalline structure of a multi-layer distributed Bragg reflector (DBR);

FIGS. 5A to 5D show a fourth embodiment of this invention; and

FIGS. 6A to 6D illustrate structure combination of the first and the fourth embodiment.

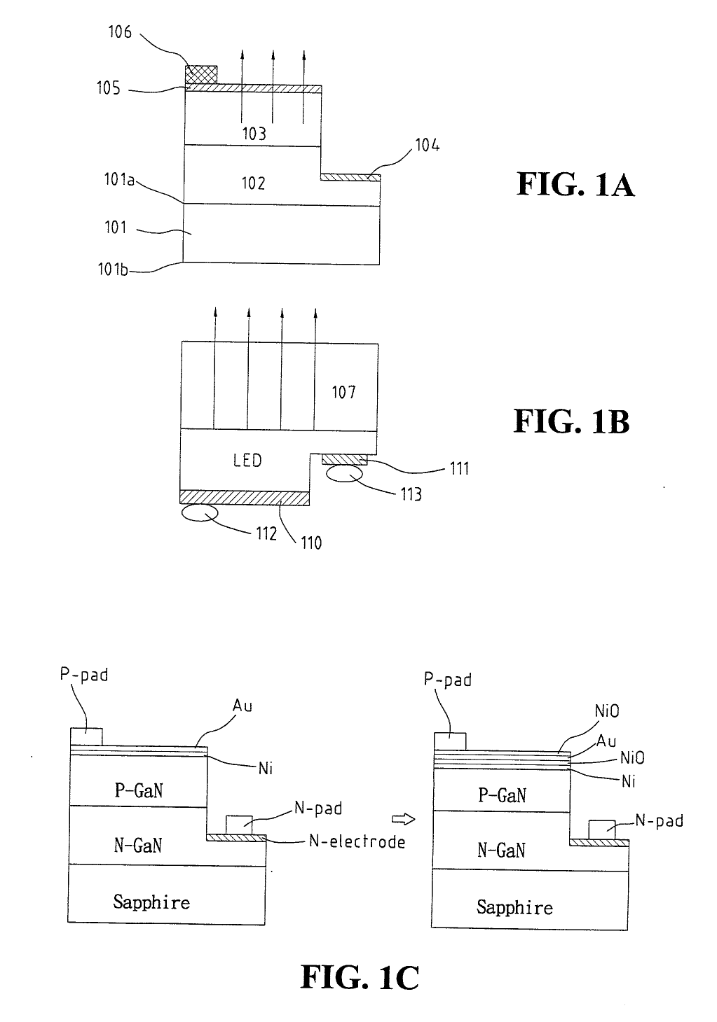

### DETAILED DESCRIPTION OF THE PREFERRED EMBODIMENT

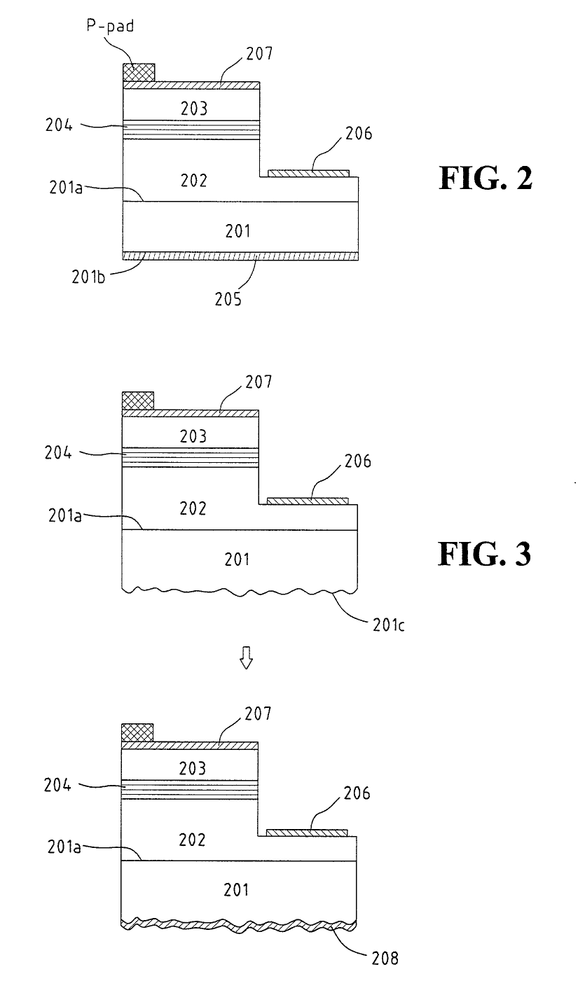

A high-brightness blue-light emitting crystalline structure in a first embodiment of this invention shown in FIG. 2 comprises:

a sapphire-made transparent substrate 201 having a first and a second surface 201a, 201b;

a semiconductor stack layer formed on the first surface 201a of the transparent substrate 201 being provided at least with an N-GaN series semiconductor layer of group III-V compounds 202 and a P-GaN series semiconductor layer of group III-V compounds 203, wherein a multiple-quantum-well structured illuminating layer 204 is formed between those two N-GaN series and P-GaN series semiconductor layers 202,203;

a plated mirror layer 205 formed and plated on the second surface 201b of the transparent substrate 201, which, the mirror layer 205 in thickness of 1 nm˜10 μm, may be formed by any of the following metallic elements including aluminum, nickel, silver, titanium, copper, aurum, beryllium-aurum, germanium-aurum, nickel-aurum-germanium, etc, or their alloys and which, the mirror layer 205, may be a physical membrane formed by means of vacuum vapor plating (plating with hot vapor, vapor plating with electronic gun, vapor plating with electric arc, etc) or vacuum sputtering, or, it may be a chemical membrane formed by means of electroplating or non-electricity plating, or by any other metal-plating process available;

a first electrode 206 provided for connection with the N-GaN series semiconductor layer of group III-V compounds 202; and

a second electrode 207 provided for connection with the P-GaN series semiconductor layer of group III-V compounds 203.

A second embodiment of this invention shown in FIG. 3 is structured mostly alike the first one but differs from the latter in that the second surface 201b of the transparent substrate 201 is requested to undergo a coarsening grinding process to form a coarse second surface 201c, then a plated mirror layer 208, wherein the coarse index of the second surface 201c is about 5˜20 μm which can be achieved by using a lapping machine pairing with diamond grinding powder of different grain sizes for control of the coarse index of the second surface 201b when grinding. Other machines with the like function, such as a grinding machine or a polishing machine may also be applied in his embodiment, however, the hardness of grinding powder (paste) or sanding paper to be applied must be harder than or at least even with that of the sapphire of the transparent substrate 201, such as SiC, corundum, or diamond powder (paste).

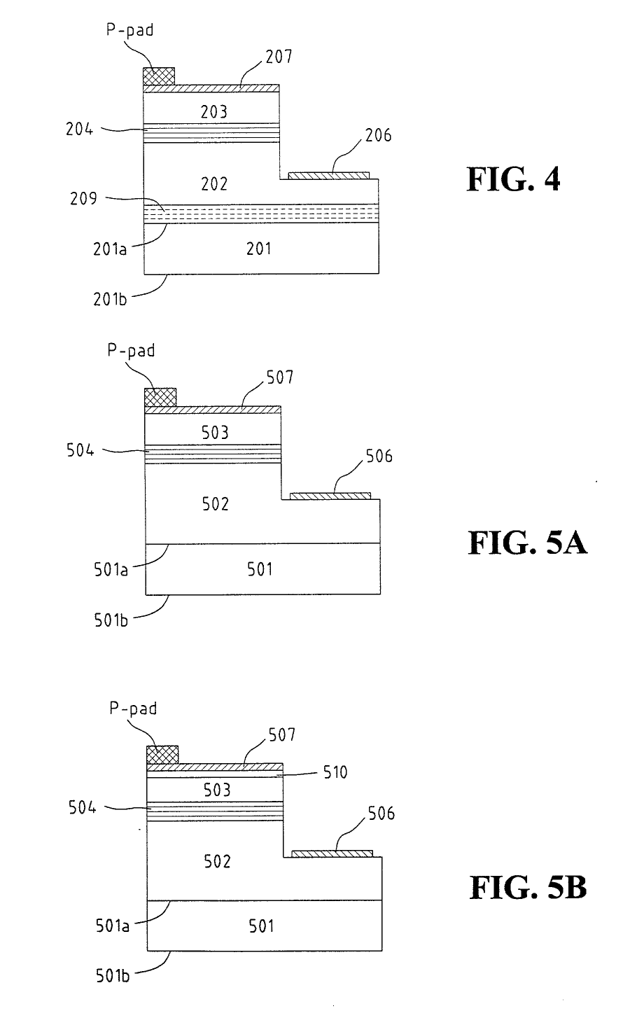

A third embodiment of this invention shown in FIG. 4 is structured mostly alike the first one but differs from the latter in that the third embodiment is provided with an additional multi-layer distributed Bragg reflector (DBR) 209 which is formed on the first surface 201a of the transparent substrate 201 by the material of (AlₓGa₁₋ₓ)_{1-y}In_{y}N/(AlₐGa₁₋ₐ)_{1-b}In_{b}N (where x>a) with epitaxial layer in n pairs (where n=5˜50), wherein the thickness of each epitaxial layer is correspondent to one-fourth of blue-light wavelength. The DBR 209 is formed by a metallic organic chemical vapor deposition (CVD) method and completed just once and for all during growing InGaN blue-light wafers, and meanwhile, the reflection index in each layer of the DBR 209 must be strictly controlled such that the structure of this invention can enlarge LED's illuminating intensity by 35% up.

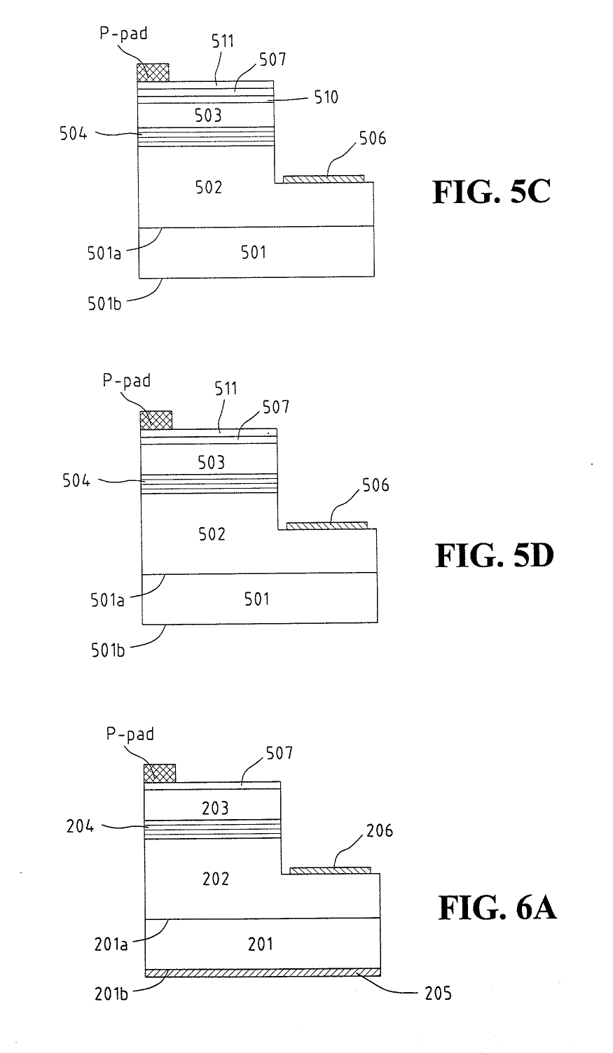

A high-brightness blue-light emitting crystalline structure in a fourth embodiment of this invention shown in FIGS. 5A through 5D comprises: a transparent substrate 501 having a first and a second surface 501a, 501b;

a semiconductor stack layer formed on the first surface 501a of the transparent substrate 501 being provided at least with an N-GaN series semiconductor layer of group III-V compounds 502 and a P-GaN series semiconductor layer of group III-V compounds 503, wherein a multiple-quantun-well structured illuminating layer 504 is formed between those two N-GaN series and P-GaN series semiconductor layers 502, 503;

a first electrode 506 provided for connection with the N-GaN series semiconductor layer of group III-V compounds 502; and

a second electrode 507 being a light-permeable electrode provided for connection with the P-GaN series semiconductor layer of group III-V compounds 503, which, the second electrode 507 shown in FIG. 5A, may be a light-permeable electrically conductive layer of indium tin oxide (ITO), which can be formed by vapor plating with electronic gun or hot vapor, or by vacuum sputtering, or as shown in FIG. 5B, a predetermined extraordinarily thin Ni/Au layer 510 in thickness of 0.1˜10 nm is located under the ITO conductive layer 507 and between the same and the semiconductor stack layer, or irrespective of the Ni/Au layer 510, a plurality of anti-reflection coatings (ARC) 511 shown in FIGS. 5C and 5D are formed on the ITO layer 507, which, the ARC 511, are made in SiO₂/TiO₂ or AlN/AlGaN with n-pair layers (n=5˜50), and the thickness of each layer is about one half of the blue-light wavelength.

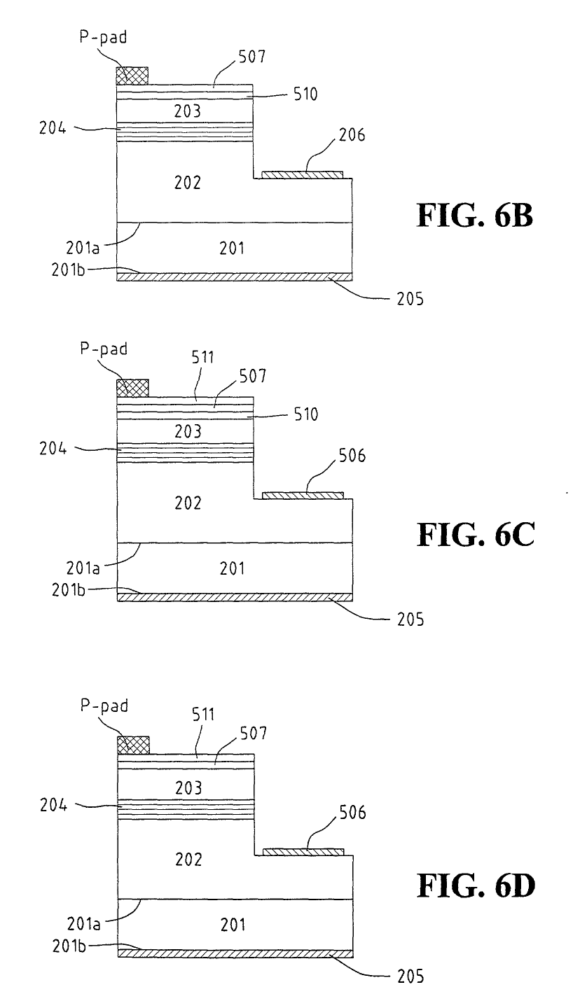

A fifth embodiment of this invention is considered structure combinations of the first all the way up to the fourth embodiment to express more brightness and reliability. As illustrated in FIGS. 6A through 6D, the fifth embodiment adopts the plated mirror layer 205 of the first embodiment, whereon the second surface 201b is coated to shield the transparent substrate 201, and the ITO layer 507 applied in the fourth embodiment. Other combinations of the embodiments can be made in any way seen fitful or preferable.

In the above described, at least one preferred embodiment has been described in detail with reference to the drawings annexed, and it is apparent that numerous variations or modifications may be made without departing from the true spirit and scope thereof, as set forth in the claims below.

What is claimed is:

1. A high-brightness blue-light emitting crystalline structure, comprising:
a transparent substrate having a first and a second surface;
a semiconductor stack layer formed on the first surface of the transparent substrate being provided at least with an N-GaN series semiconductor layer of group III-V compounds and a P-GaN series semiconductor layer of group III-V compounds, wherein a multiple-quantum-well structured illuminating layer is formed between those two N-GaN series and P-GaN series semiconductor layers;
a plated mirror layer formed and plated on the second surface of the transparent substrate;
a first electrode provided for connection with the N-GaN series semiconductor layer of group III-V compounds; and
a second electrode made of a light-permeable material being provided for connection with the P-GaN series semiconductor layer of group III-V compounds.

2. The structure according to claim 1, wherein the plated mirror layer is made of any of the following materials including: aluminum, nickel, silver, titanium, copper, aurum, beryllium-aurum, germanium-aurum, nickel-aurum-germanium, etc, or their alloys, and the thickness of the plated mirror layer is 1 nm˜10 μm.

3. A high-brightness blue-light emitting crystalline structure, comprising:
a transparent substrate having a first and a coarsened second surface;
a semiconductor stack layer formed on the first surface of the transparent substrate being provided at least with an N-GaN series semiconductor layer of group III-V compounds and a P-GaN series semiconductor layer of group III-V compounds;
a coarsened mirror layer formed to cover the coarsened second surface of the transparent substrate;
a first electrode provided for connection with the N-GaN series semiconductor layer of group III-V compounds; and
a second electrode made of a light-permeable material being provided for connection with the P-GaN series semiconductor layer of group III-V compounds.

4. The structure according to claim 3, wherein the coarse index of the coarsened second surface is about 5˜20 μm.

5. A high-brightness blue-light emitting crystalline structure, comprising:
a transparent substrate having a first and a coarsened second surface;
a plurality of multi-layer distributed Bragg reflectors (DBR) formed on the first surface of the transparent substrate;
a semiconductor stack layer formed on the first surface of the transparent substrate being provided at least with an N-GaN series semiconductor layer of group III-V compounds and a P-GaN series semiconductor layer of group III-V compounds;
a first electrode provided for connection with the N-GaN series semiconductor layer of group III-V compounds; and
a second electrode made of a light-permeable material being provided for connection with the P-GaN series semiconductor layer of group III-V compounds.

6. The structure according to claim 5, wherein the material of the multi-layer distributed Bragg reflector is (AlₓGa₁₋ₓ)_{1-y}In_{y}N/(AlₐGa₁₋ₐ)_{1-b}In_{b}N (where x>a) with epitaxial layer in n pairs (where n=5˜50), wherein the thickness of each epitaxial layer is correspondent to one-fourth of blue-light wavelength.

7. A high-brightness blue-light emitting crystalline structure, comprising:
a transparent substrate having a first and a coarsened second surface;
a semiconductor stack layer formed on the first surface of the transparent substrate being provided at least with an N-GaN series semiconductor layer of group III-V compounds and a P-GaN series semiconductor layer of group III-V compounds;
a first electrode provided for connection with the N-GaN series semiconductor layer of group III-V compounds; and
a second electrode provided for connection with the P-GaN series semiconductor layer of group III-V compounds being a transparent conductive layer made of light permeable indium tin oxide (ITO).

8. The structure according to claim 7, wherein an extraordinarily thin Ni/Au layer is predeterminately arranged under the ITO transparent conductive layer and between the same and the semiconductor stack layer, and the thickness of the Ni/Au layer is 0.1˜10 nm.

9. The structure according to claim 7, wherein a plurality of anti-reflection coatings (ARC) are formed on the ITO transparent conductive layer; the ARC are made in SiO₂/TiO₂ or AlN/AlGaN with n-pair layers (n=5˜50); and the thickness of each layer is about one half of the blue-light wavelength.

10. The structure according to claim 8, wherein a plurality of anti-reflection coatings (ARC) are formed on the ITO transparent conductive layer; the ARC are made in SiO₂/TiO₂ or AlN/AlGaN with n-pair layers (n=5˜50); and the thickness of each layer is about one half of the blue-light wavelength.

11. A high-brightness blue-light emitting crystalline structure according to claim 1, claim 3, or claim 5, wherein the light permeable second electrode is substantially an electrically conductive transparent electrode made of Indium tin oxide (ITO).

12. The structure according to claim 11, wherein an extraordinarily thin Ni/Au layer is predeterminately arranged under the ITO transparent conductive layer and between the same and the semiconductor stack layer, and the thickness of the Ni/Au layer is 0.1˜10 nm.

13. The structure according to claim 11, wherein a plurality of anti-reflection coatings (ARC) are formed on the ITO transparent conductive layer; the ARC are made in SiO₂/TiO₂ or AlN/AlGaN with n-pair layers (n=5˜50); and the thickness of each layer is about one half of the blue-light wavelength.

14. The structure according to claim 12, wherein a plurality of anti-reflection coatings (ARC) are formed on the ITO transparent conductive layer; the ARC are made in SiO₂/TiO₂ or AlN/AlGaN with n-pair layers (n=5˜50); and the thickness of each layer is about one half of the blue-light wavelength.
